(19) United States
(12) Patent Application Publication
(10) Pub. No.: US 2024/0038793 A1
(43) Pub. Date: Feb. 1, 2024

(54) ARRAY SUBSTRATE AND MANUFACTURING METHOD THEREOF

(71) Applicant: Wuhan China Star Optoelectronics Technology Co., Ltd., Wuhan, Hubei (CN)

(72) Inventors: Fei AI, Wuhan, Hubei (CN); Fan GONG, Wuhan, Hubei (CN); Jiyue SONG, Wuhan, Hubei (CN); Dewei SONG, Wuhan, Hubei (CN); Shiyu LONG, Wuhan, Hubei (CN)

(73) Assignee: Wuhan China Star Optoelectronics Technology Co., Ltd., Wuhan, Hubei (CN)

(21) Appl. No.: 17/278,342

(22) PCT Filed: Dec. 31, 2020
(86) PCT No.: PCT/CN2020/142362

§ 371 Date: Oct. 12, 2023

(30) Foreign Application Priority Data
Dec. 30, 2020 (CN) 202011603545.3

(51) Int. Cl. H01L 27/146

(52) U.S. Cl. CPC H01L 27/14612; H01L 27/14649; H01L 27/14683

(57) ABSTRACT

An array substrate and a manufacturing method thereof are provided. The array substrate includes a thin film transistor layer including a first thin film transistor and an infrared detection element disposed on a first side of the thin film transistor layer. The infrared detection element includes a first electrode, a light-absorbing layer, and a second electrode sequentially stacked, wherein the infrared detection element is electrically connected to the first thin film transistor, and wherein a material of the light-absorbing layer is microcrystalline silicon. A thickness and band gap of the microcrystalline silicon simultaneously fulfill a purpose of infrared detection.

### FIELD OF INVENTION

The application relates to the field of display technology and in particular to an array substrate and a manufacturing method thereof.

### BACKGROUND OF INVENTION

In recent years, with progress in the display panel industry, users have higher requirements for display panels. Diversifying functions of display panels and enhancing human-computer interactions to improve competitiveness of display panels is a main development direction for the current display panels. Infrared detection elements are widely used in mobile phones, computers, and wearable electronic devices. A light-absorbing layer of current infrared detection element usually adopts monocrystalline silicon and indium gallium arsenide (InGaAs) materials. However, a growth temperature of the monocrystalline silicon (900° C.) is much higher than an upper limit temperature (600° C.) in the display panel manufacturing process. The growth process of indium gallium arsenide, i.e., molecular beam epitaxy (MBE) growth process is not compatible with a display panel production line. Therefore, development of an array substrate compatible with infrared detection elements is a development focus for the display panel industry.

### Technical Problem

In order to solve the above-mentioned problems, the present application provides an array substrate integrated with infrared detection elements and a manufacturing method thereof.

### SUMMARY OF INVENTION

### Technical Solution

The application provides an array substrate. The array substrate includes a thin film transistor layer and an infrared detection element.

The thin film transistor layer includes a first thin film transistor.

The infrared detection element disposed on a first side of the thin film transistor layer. The infrared detection element includes a first electrode, a light-absorbing layer, and a second electrode sequentially stacked on the first side of the thin film transistor layer. The infrared detection element is electrically connected to the first thin film transistor.

A material of the light-absorbing layer is microcrystalline silicon.

In some embodiments, a thickness of the light-absorbing layer ranges from 60 nm to 3000 nm, and a band gap of the light-absorbing layer ranges from 1.1 eV to 1.5 eV.

In some embodiments, the thickness of the light-absorbing layer ranges from 300 nm to 3000 nm.

In some embodiments, an orthographic projection of the infrared detection element on the thin film transistor layer is positioned within a boundary of the first thin film transistor.

In some embodiments, the first electrode is electrically connected to a source/drain of the first thin film transistor.

In some embodiments, the infrared detection element further includes a first semiconductor layer, and the first semiconductor layer is positioned between the first electrode and the light-absorbing layer.

In some embodiments, the infrared detection element further includes a second semiconductor layer, and the second semiconductor layer is positioned between the light-absorbing layer and the second electrode.

In some embodiments, the infrared detection element further includes a first semiconductor layer and a second semiconductor layer, the first semiconductor layer is positioned between the first electrode and the light-absorbing layer, and the second semiconductor layer is positioned between the light-absorbing layer and the second electrode.

In some embodiments, a material of the first semiconductor layer is n-type amorphous silicon, and a material of the second semiconductor layer is p-type amorphous silicon.

In some embodiments, a material of the first semiconductor layer is n-type microcrystalline silicon, and a material of the second semiconductor layer is p-type microcrystalline silicon.

In some embodiments, the array substrate further includes a second thin film transistor and a pixel electrode electrically connected to the second thin film transistor, and the pixel electrode and the second electrode are positioned in the same layer.
a source/drain of the first thin film transistor and a source/drain of the second thin film transistor are positioned in a same layer of the array substrate, a gate of the first thin film transistor and a gate of the second thin film transistor are positioned in a same layer of the array substrate, and an active layer of the first thin film transistor and an active layer of the second thin film transistor are positioned in a same layer of the array substrate.

This application further provides a method of manufacturing an array substrate.

The method includes following steps:
forming a thin film transistor layer which includes a first thin film transistor; and
sequentially forming a first electrode, a light-absorbing layer, and a second electrode on a first side of the thin film transistor layer to form an infrared detection element and electrically connecting the infrared detection element to the first thin film transistor, wherein a material of the light-absorbing layer is microcrystalline silicon.

In some embodiments, the microcrystalline silicon is formed by a plasma-enhanced chemical vapor deposition process.

In some embodiments, a thickness of the light-absorbing layer ranges from 60 nm to 3000 nm, and a band gap of the light-absorbing layer ranges from 1.1 eV to 1.5 eV.

In some embodiments, the thickness of the light-absorbing layer ranges from 300 nm to 3000 nm.

In some embodiments, an orthographic projection of the infrared detection element on the thin film transistor layer is positioned within a boundary of the first thin film transistor.

In some embodiments, the first electrode is electrically connected to a source/drain of the first thin film transistor.

In some embodiments, the step of forming the infrared detection element further includes: providing a first semiconductor layer between the first electrode and the light-absorbing layer and providing a second semiconductor layer between the light-absorbing layer and the second electrode.

In some embodiments, a material of the first semiconductor layer is n-type amorphous silicon, and a material of the second semiconductor layer is p-type amorphous silicon.

### Advantageous Effect

Compared with prior art, this application has following beneficial effects and advantages:

The present application provides an array substrate. In the array substrate, an infrared detection element includes a first electrode, a light-absorbing layer, and a second electrode sequentially stacked on the first side of the thin film transistor layer, wherein the infrared detection element is electrically connected to the first thin film transistor, and wherein the material of the light-absorbing layer is microcrystalline silicon. The microcrystalline silicon can meet the requirements of infrared detection applied to display panels, which improves the accuracy of infrared detection. The manufacturing process of the light-absorbing layer can be integrated into display panel production lines, and the display panel production lines are fully compatible with the manufacturing process of the light-absorbing layer, which is beneficial to realize large-scale industrial production and application.

### DESCRIPTION OF DRAWINGS

FIG. 1 is a structural schematic diagram of a cross-section of an array substrate provided by an embodiment of the application.

FIG. 2 is a flowchart of a method of manufacturing an array substrate provided by an embodiment of the application.

### DETAILED DESCRIPTION OF PREFERRED EMBODIMENTS

The technical solutions in the embodiments of the present application will be clearly and completely described with reference to the drawings in the embodiments of the present application. Based on the embodiments in the present application, all other embodiments obtained by those skilled in the art without doing creative work fall within the protection scope of this application.

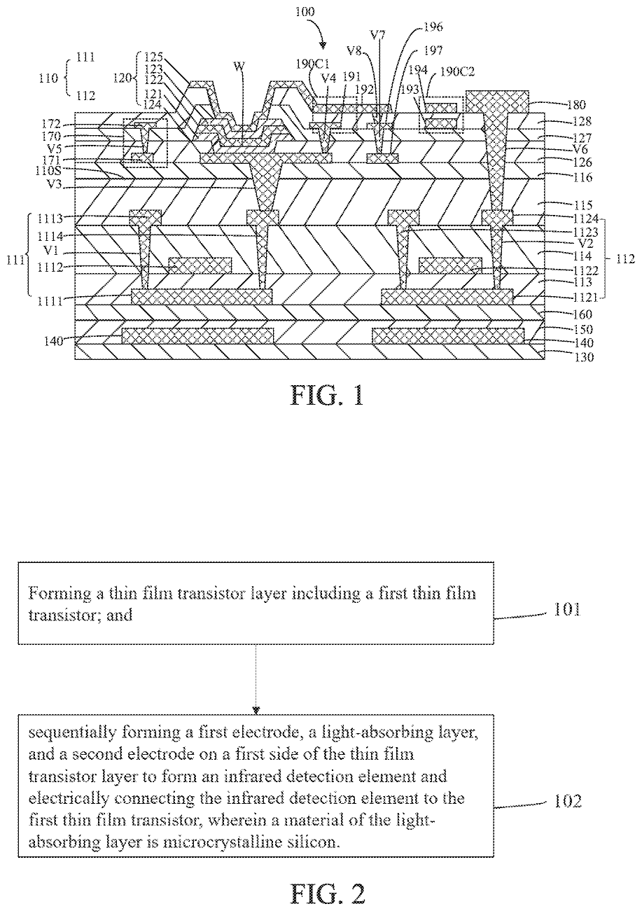

FIG. 1 is a schematic structural diagram of a cross section of an array substrate 100 provided by an embodiment of the application. As shown in FIG. 1, the array substrate 100 includes a thin film transistor layer 110, and the thin film transistor layer 110 includes a first thin film transistor 111.

An infrared detection element 120 is disposed on a first side 1105 of the thin film transistor layer 110, and the first side 1105 is an upper side of the thin film transistor layer 110. The infrared detection element 120 includes a first electrode 124, a light-absorbing layer 122, and a second electrode 125 which are sequentially stacked on the first side 1105, and the infrared detection element 120 is electrically connected to the first thin film transistor 111. The first thin film transistor 111 is configured to provide a reverse bias voltage for the infrared detection element 120.

The infrared detection element 120 of this embodiment is composed of a first electrode 124, a light-absorbing layer 122, and a second electrode 125, and an intermediate layer is omitted. On the condition that a purpose of infrared detection fulfilled, a manufacturing process can be simplified, a thickness of the panel can be reduced, and production costs can be saved.

A material of the light-absorbing layer 122 is microcrystalline silicon. Materials of the light-absorbing layer in the prior art are usually polysilicon and amorphous silicon. However, due to limitations of the growth process of polysilicon, thickness of polysilicon is too small (less than 45 nanometers) to absorb enough light, which affects the accuracy of infrared detection. Although the current process can produce amorphous silicon with sufficient thickness, band gap of amorphous silicon whose thickness meets the requirements cannot meet the requirements of infrared detection. The use of microcrystalline silicon in the light-absorbing layer of this embodiment can meet the infrared detection requirements of the display panel in terms of thickness (greater than 45 nm) and band gap and improve the accuracy of infrared detection.

A manufacturing process of the microcrystalline silicon can be integrated into a display panel production line. For example, a low-temperature poly silicon (LTPS) process can be compatible with a manufacturing process of the light-absorbing layer 122, and the compatibility is relatively high, which is conducive to large-scale industrial production and applications.

In some embodiments, a thickness of the light-absorbing layer 122 is between 60 nanometers and 3000 nanometers, for example, the thickness can be 100 nanometers, 200 nanometers, 500 nanometers, 1000 nanometers, 1500 nanometers, or 2000 nanometers. Meanwhile, the band gap is between 1.1 eV and 1.5 eV, for example, the band gap can be 1.2 eV, 1.3 eV, or 1.4 eV. Its thickness and band gap enable the infrared detection element 120 to achieve the purpose of infrared detection.

In some embodiments, the thickness of the light-absorbing layer 122 ranges from 300 nm to 3000 nm, for example, it may be 400 nm, 800 nm, 1700 nm, or 2500 nm. The microcrystalline silicon within this thickness range can absorb more light and improve the accuracy of infrared detection.

In some embodiments, an orthographic projection of the infrared detection element 120 on the thin film transistor layer 110 is positioned within a boundary of the first thin film transistor 111.

Specifically, the infrared detection element 120 is positioned directly above the first thin film transistor 111, which can prevent reduction of the aperture ratio of the display panel due to introduction of the infrared detection element 120.

In some embodiments, the infrared detection element 120 is connected to a source/drain of the first thin film transistor 111 through the first electrode 124.

In some embodiments, the infrared detection element 120 further includes a first semiconductor layer 121, and the first semiconductor layer 121 is positioned between the first electrode 124 and the light-absorbing layer 122. In this embodiment, the first semiconductor layer 121 is provided between the first electrode 124 and the light-absorbing layer 122. The first semiconductor layer 121 can suppress generation of leakage current caused by direct contact between the first electrode 124 and the light-absorbing layer 122. It can also absorb part of visible light, which further assists the absorption of infrared light by the light-absorbing layer 122, thereby improving the detection sensitivity of the infrared detection element 120.

In some embodiments, the infrared detection element 120 further includes a second semiconductor layer 123, and the second semiconductor layer 123 is positioned between the light-absorbing layer 122 and the second electrode 125. In this embodiment, a second semiconductor layer 123 is provided between the light-absorbing layer 122 and the second electrode 125. The second semiconductor layer 123 can prevent leakage current caused by a direct contact between the light-absorbing layer 122 and the second electrode 125. It can also absorb part of visible light, which further assists the absorption of infrared light by the light-absorbing layer 122, thereby improving the detection sensitivity of the infrared detection element 120.

In some embodiments, the infrared detection element 120 further includes a first semiconductor layer 121 and a second semiconductor layer 123. The first semiconductor layer 121 is positioned between the first electrode 124 and the light-absorbing layer 122, and the second semiconductor layer 123 is positioned between the light-absorbing layer 122 and the second electrode 125. The first semiconductor 121 and the second semiconductor 123 serve as a charge transport layer and a built-in electric field building layer to suppress dark current and separate photogenerated electrons and holes. Compared a situation in which the first semiconductor 121 or the second semiconductor 123 is formed only on one side of the light-absorbing layer 122, the generation of leakage current can be further suppressed. The light-absorbing layer 122 is configured to absorb infrared light.

In some embodiments, the material of the first semiconductor layer 121 is n-type amorphous silicon or n-type microcrystalline silicon.

In some embodiments, the material of the second semiconductor layer 123 is p-type amorphous silicon or p-type microcrystalline silicon.

Specifically, n-type amorphous silicon and p-type amorphous silicon, or n-type microcrystalline silicon and p-type microcrystalline silicon, are formed on both sides of the light-absorbing layer 122, respectively. It can suppress the generation of leakage current, detect light with low light intensity, and improve the sensitivity of infrared detection. In one embodiment, the material of the first semiconductor layer 121 is n-type amorphous silicon, and the material of the second semiconductor layer 122 is p-type amorphous silicon, which can reduce commissioning costs and reduce visible light interference.

In some embodiments, the array substrate 100 further includes a second thin film transistor 112 and a pixel electrode 180 electrically connected to the second thin film transistor 112, and the pixel electrode 180 and the second electrode 125 are disposed in a same layer.

In some embodiments, a source/drain of the first thin film transistor 111 and a source/drain of the second thin film transistor 112 are positioned in a same layer of the array substrate 100. A gate of the first thin film transistor 111 and a gate of the second thin film transistor 112 are positioned in the same layer of the array substrate 100. An active layer of the first thin film transistor 111 and an active layer of the second thin film transistor 112 are positioned in the same layer of the array substrate 100. A same mask can be used to form functional layers in the same layer, which can save manufacturing costs and production cycles.

Specifically, the array substrate 100 further includes a substrate 130, a light-shielding layer 140 on the substrate 130, a first spacer layer 150 covering the light-shielding layer 140, and a second spacer layer 160 on the first spacer layer 150. The thin film transistor layer 110 is disposed on the second spacer layer 160.

As shown in FIG. 1, in this embodiment, the first thin film transistor 111 and the second thin film transistor 112 may have a bottom gate structure. The first thin film transistor 111 includes a first active layer 1111, a first gate 1112, a first source 1113, and a first drain 1114. Similarly, the second thin film transistor 112 includes a second active layer 1121, a second gate 1122, a second source 1123, and a second drain 1124. The first active layer 1111 and the second active layer 1121, the first gate 1112 and the second gate 1122, the first source 1113 and the second source 1123, and the first drain 1114 and the second drain 1124 are positioned in the same layer of the array substrate 100. Arranging the first thin film transistor 111 and the second thin film transistor 112 in a same layer can save the use of masks, simplify an entire manufacturing process of the array substrate involved in the present application, and reduce the production costs and production cycles of the array substrate 100.

The pixel electrode 180 is electrically connected to a second drain 1124 of the second thin film transistor 112.

In some embodiments, the array substrate 100 further includes touch electrodes 170, and the touch electrodes 170 include electrode lines 171 and pads 172 electrically connected to the electrode lines 171. In some embodiments, the electrode line 171 of the touch electrode 170 and the first electrode 124 of the infrared detection element 120 are disposed in a same layer. This structure can also reduce manufacturing processes of the photomask.

In some embodiments, the array substrate 100 further includes a sensor capacitor 190C1. As shown in FIG. 1, a first bottom electrode 191 is disposed above the first electrode 124 of the infrared detection element 120 and is electrically connected to the first electrode 124. The corresponding first top electrode 192 and the second electrode 125 of the infrared detection element 120 are electrically connected and disposed in the same layer. The first bottom electrode 191 and the first top electrode 192 constitute a sensor capacitor 190C1 as shown in FIG. 1. The sensor capacitor 190C1 makes the voltage used to control the first thin film transistor 111 more stable. The sensor capacitor 190C1 is also connected to a Com potential. Specifically, the first top electrode 192 of the sensor capacitor 190C1 is electrically connected to a common electrode 197. The common electrode 197 and the first electrode 124 of the infrared detection element 120 are disposed in a same layer. In some embodiments, in order to improve the stability of the sensor capacitor 190C1, the first top electrode 192 is electrically connected to the common electrode 197 through a transition layer 196. The transition layer 196 can be disposed in a same layer as the first bottom electrode 191 of the infrared detection element 120.

Of course, the array substrate 100 further includes a pixel capacitor 190C2. A second bottom electrode 193 and the first bottom electrode 191 of the sensor capacitor 190C1 are disposed in a same layer, and a second top electrode 194 and the first top electrode 192 of the sensor capacitor 190C1 are disposed in a same layer. The structural layers disposed in a same layer use a same photomask, which reduces manufacturing processes and production cycles of the array substrate. The second bottom electrode 193 and the second top electrode 194 constitute a pixel capacitor 190C2 as shown in FIG. 1.

This embodiment provides an array substrate. In the array substrate, the infrared detection element includes a first electrode, a light-absorbing layer, and a second electrode stacked in sequence. The infrared detection element is electrically connected to the first thin film transistor. The material of the light-absorbing layer is microcrystalline silicon. The microcrystalline silicon can simultaneously meet requirements of infrared detection of the display panel in terms of thickness and band gap. The manufacturing process of the light-absorbing layer is integrated into the display panel production line. The display panel production line is fully compatible with the manufacturing process of the light-absorbing layer, which is conducive to large-scale industrial production and applications.

FIG. 2 is a flowchart of a method of manufacturing an array substrate provided by an embodiment of the application. With reference to FIG. 1, as shown in FIG. 2, the method of manufacturing includes following steps:

Step 101: forming a thin film transistor layer 110, the thin film transistor layer 110 includes a first thin film transistor 111.

In some embodiments, the thin film transistor layer 110 further includes a second thin film transistor 112 and a pixel electrode 180 electrically connected to the second thin film transistor 112.

Specifically, a substrate 130 is provided, a light-shielding layer 140 is deposited on the substrate 130, and then a pattern of the light-shielding layer 140 is formed by exposure and etching. A first spacer layer 150 and a second spacer layer 160 are sequentially deposited and formed on the substrate 130. An active layer is deposited on the second spacer layer 160, and the material used for the active layer is amorphous silicon (a-Si), which is subjected to excimer laser annealing (ELA) or solid phase crystallization (SPC) to convert the amorphous silicon into polysilicon (poly-Si). When the laser annealing method is used, lasers including XeC1 laser, ArF laser, KrF laser, XeF laser, etc. are generally used. These types of laser beams irradiate amorphous silicon in the active layer with a short pulse laser beam in the ultraviolet band. Amorphous silicon will quickly absorb laser energy to be melted and recrystallized. Then, the active layer is subjected to exposure, development, etch, and stripping processes using a mask to form a first active layer 1111 and a second active layer 1121. An ion implantation process is performed on the first active layer 1111 and the second active layer 1121 to form a source region and a drain region. In some embodiments, the ion implantation adopts P-ion doping. A gate insulating layer 113 and a gate layer provided thereon are deposited on the second spacer layer 160, and the gate layer is patterned by a re-etch process to form a first gate 1112 and a second gate 1122. An interlayer dielectric layer 114 is deposited on the gate insulating layer 113 and is patterned to form a first via hole V1 and a second via hole V2. A source/drain layer is deposited on the interlayer dielectric layer 114, and the source/drain layer is patterned to form a first source 1113 and a first drain 1114 of the first thin film transistor 111 and a second source 1123 and a second drain 1124 of the second thin film transistor 112. A planarization layer 115 is covered on the interlayer dielectric layer 114, a first passivation layer 116 is deposited on the planarization layer 115, and the planarization layer 115 and the first passivation layer 116 are patterned to form a third via hole V3.

Step 102: A first electrode 124, a light-absorbing layer 122, and a second electrode 125 are sequentially formed on a first side 110 of the thin film transistor layer 110 to form an infrared detection element 120, and the infrared detection element 120 is electrically connected to the first thin film transistor 111, wherein the material of the light-absorbing layer 122 is microcrystalline silicon.

Specifically, an indium tin oxide (ITO) material is deposited on the first passivation layer 116 and patterned to form the first electrode 124. The first electrode 124 is electrically connected to the first drain 1114 of the first thin film transistor 111 through the third via hole V3 on the first passivation layer 116.

In some embodiments, the ITO material layer is patterned. The first electrode 124 and an electrode lines 171 forming a touch electrode 170 can be formed at the same time by using a same mask.

A second passivation layer 126 is deposited on the first passivation layer 116 and covers the first electrode 124. In some embodiments, the second passivation layer 126 further covers the electrode lines 171 of the touch electrode 170.

Then, the second passivation layer 126 is processed to form an opening W, exposing part of the first electrode 124, and the light-absorbing layer 122 is deposited in the opening W.

In some embodiments, a first semiconductor layer 121 and the light-absorbing layer 122 are sequentially deposited in the opening W, and the first semiconductor layer 121 is positioned between the first electrode 124 and the light-absorbing layer 122.

In some embodiments, the light-absorbing layer 122 and a second semiconductor layer 123 are sequentially deposited in the opening W, and the second semiconductor layer 123 is positioned between the light-absorbing layer 122 and the second electrode 125.

In some embodiments, the first semiconductor layer 121, the light-absorbing layer 122, and the second semiconductor layer 123 are sequentially deposited in the opening W.

In some embodiments, a material of the first semiconductor layer 121 is n-type amorphous silicon or n-type microcrystalline silicon.

In some embodiments, a material of the second semiconductor is p-type amorphous silicon or p-type microcrystalline silicon.

Specifically, n-type amorphous silicon and p-type amorphous silicon, or n-type microcrystalline silicon and p-type microcrystalline silicon, are formed on both sides of the light-absorbing layer 122, respectively. This can suppress the generation of leakage current, detect light with low light intensity, and improve the sensitivity of infrared detection. In one embodiment, the material of the first semiconductor layer 121 is n-type amorphous silicon, and the material of the second semiconductor layer 122 is p-type amorphous silicon, which can reduce commissioning costs and reduce visible light interference.

A third passivation layer 127 is deposited on the second passivation layer 126, an ITO material layer is deposited on the third passivation layer 127, and the ITO material layer is patterned to form a second bottom electrode 193 of a pixel capacitor 190C2. In some embodiments, when a patterning process is performed on the ITO material layer, a first bottom electrode 191 of the sensor capacitor 190C1 can also be formed at the same time. A fourth via hole V4 is formed in the third passivation layer 127, and the first bottom electrode 191 is electrically connected to the first electrode 124 of the infrared detection element 120 through the fourth via hole V4.

In some embodiments, the second passivation layer 126 and the third passivation layer 127 are patterned to form a fifth via hole V5. The fifth via hole V5 penetrates the second passivation layer 126 and the third passivation layer 127 and exposes a part of the electrode line 171. A touch pad 172 of the touch electrode 170 is formed on the corresponding position of the third passivation layer 127, and the touch pad 172 is electrically connected to the electrode line 171 through the fifth via hole V5.

A fourth passivation layer 128 is deposited on the third passivation layer 127, and the fourth passivation layer 128 is patterned to form a sixth via hole V6. The sixth via hole V6 penetrates the planarization layer 115, the first passivation layer 116, the second passivation layer 126, the third passivation layer 127, and the fourth passivation layer 128. A layer of ITO material is deposited on the fourth passivation layer 128 and covers the second semiconductor layer 123. The ITO material layer is subjected to a patterning process, and the second electrode 125, the first top electrode 192 of the sensor capacitor 190C1, the second top electrode 194 of the pixel capacitor 190C2, and the pixel electrode 180 are formed accordingly. The pixel electrode 180 is electrically connected to the second drain 1124 of the second thin film transistor 112 through the sixth via hole V6.

In some embodiments, the first electrode 124 and the common electrode 197 are formed using a same mask. A seventh via hole V7 is formed on the second passivation layer 126 and the third passivation layer 127, and the seventh via hole V7 penetrates the third passivation layer 127 and exposes part of the common electrode 197. The same mask is used to form the first bottom electrode 191 and the transition layer 196 of the sensor capacitor 190C1. The transition layer 196 is filled in the seventh via hole V7 and electrically connected to the common electrode 197. An eighth via hole V8 is formed on the fourth passivation layer 128, and the first top electrode 192 of the sensor capacitor 190C1 is electrically connected to the transition layer 196 through the eighth via hole V8. A transition layer 196 is disposed between the first top electrode 192 of the sensor capacitor 190C1 and the common electrode 197 to realize connection between the sensor capacitor 190C1 and the Com potential. It is necessary to avoid directly forming a via hole in the second passivation layer 126, the third passivation layer 127, and the fourth passivation layer 128 because the via hole is easily over-etched when it is formed, which reduces the stability of the sensor capacitor 190C1.

In some embodiments, the light-absorbing layer 122 is formed using a plasma-enhanced chemical vapor deposition process. Materials used are H₂ and SiH₄, and the volume of H₂ accounts for 2% to 10% of the total volume of H₂ and SiH₄. The manufacturing temperature is between 200° C. and 450° C., and the pressure is between 1000 mtor and 3000 mtor. The process parameters of the plasma-enhanced chemical vapor deposition process for manufacturing the microcrystalline silicon material are within an acceptable range of the display panel production line, and the display panel production line is fully compatible with the manufacturing process of the light-absorbing layer 122, which is conducive to mass production.

A method of manufacturing an array substrate is provided by this embodiment. In the manufacturing method, the plasma-enhanced chemical vapor deposition process is used to form microcrystalline silicon, which is used as a light-absorbing layer of an infrared detection element to achieve the purpose of photosensitive detection. The manufacturing process of the light-absorbing layer can be integrated into a display panel production line, which is beneficial to realizing mass production of display products integrated with infrared detection elements. In addition, the first thin film transistor and the second thin film transistor are formed in a same layer, which can save the use of masks, simplify the manufacturing process of the array substrate, and shorten the production cycle.

An array substrate and manufacturing method thereof provided by the present application are described in detail above. In this article, specific embodiments are used to illustrate the principles and implementation of the present application. The description of the implementation is to help understand the technical solutions and core ideas of the present application. Those of ordinary skill in the art should understand that they can still modify the technical solutions described in the embodiments, or equivalently replace some of the technical features. However, these modifications or replacements do not cause the essence of the corresponding technical solutions to deviate from the scope of the technical solutions of the embodiments of the present application.

What is claimed is:

1. An array substrate, comprising:
a thin film transistor layer comprising a first thin film transistor; and
an infrared detection element disposed on a first side of the thin film transistor layer, wherein the infrared detection element comprises a first electrode, a light-absorbing layer, and a second electrode sequentially stacked on the first side of the thin film transistor layer, wherein the infrared detection element is electrically connected to the first thin film transistor, and wherein a material of the light-absorbing layer is microcrystalline silicon.

2. The array substrate according to claim 1, wherein a thickness of the light-absorbing layer ranges from 60 nm to 3000 nm, and a band gap of the light-absorbing layer ranges from 1.1 eV to 1.5 eV.

3. The array substrate according to claim 2, wherein the thickness of the light-absorbing layer ranges from 300 nm to 3000 nm.

4. The array substrate according to claim 1, wherein an orthographic projection of the infrared detection element on the thin film transistor layer is positioned within a boundary of the first thin film transistor.

5. The array substrate of claim 1, wherein the first electrode is electrically connected to a source/drain of the first thin film transistor.

6. The array substrate according to claim 1, wherein the infrared detection element further comprises a first semiconductor layer, and the first semiconductor layer is positioned between the first electrode and the light-absorbing layer.

7. The array substrate according to claim 1, wherein the infrared detection element further comprises a second semiconductor layer, and the second semiconductor layer is positioned between the light-absorbing layer and the second electrode.

8. The array substrate according to claim 1, wherein the infrared detection element further comprises a first semiconductor layer and a second semiconductor layer, the first semiconductor layer is positioned between the first electrode and the light-absorbing layer, and the second semiconductor layer is positioned between the light-absorbing layer and the second electrode.

9. The array substrate according to claim 8, wherein a material of the first semiconductor layer is n-type amorphous silicon, and a material of the second semiconductor layer is p-type amorphous silicon.

10. The array substrate according to claim 8, wherein a material of the first semiconductor layer is n-type microcrystalline silicon, and a material of the second semiconductor layer is p-type microcrystalline silicon.

11. The array substrate according to claim 1, wherein the array substrate further comprises a second thin film transistor and a pixel electrode electrically connected to the second thin film transistor, and the pixel electrode and the second electrode are positioned in a same layer.

12. The array substrate according to claim 11, wherein a source/drain of the first thin film transistor and a source/drain of the second thin film transistor are positioned in a same layer of the array substrate, a gate of the first thin film transistor and a gate of the second thin film transistor are positioned in a same layer of the array substrate, and an active layer of the first thin film transistor and an active layer of the second thin film transistor are positioned in a same layer of the array substrate.

13. A method of manufacturing an array substrate, comprising following steps:
forming a thin film transistor layer comprising a first thin film transistor; and
sequentially forming a first electrode, a light-absorbing layer, and a second electrode on a first side of the thin film transistor layer to form an infrared detection element and electrically connecting the infrared detection element to the first thin film transistor, wherein a material of the light-absorbing layer is microcrystalline silicon.

14. The method of manufacturing the array substrate according to claim 13, wherein the microcrystalline silicon is formed by a plasma-enhanced chemical vapor deposition process.

15. The method of manufacturing the array substrate according to claim 13, wherein a thickness of the light-absorbing layer ranges from 60 nm to 3000 nm, and a band gap of the light-absorbing layer ranges from 1.1 eV to 1.5 eV.

16. The method of manufacturing the array substrate according to claim wherein the thickness of the light-absorbing layer ranges from 300 nm to 3000 nm.

17. The method of manufacturing the array substrate according to claim 13, wherein an orthographic projection of the infrared detection element on the thin film transistor layer is positioned within a boundary of the first thin film transistor.

18. The method of manufacturing the array substrate according to claim 13, wherein the first electrode is electrically connected to a source/drain of the first thin film transistor.

19. The method of manufacturing the array substrate according to claim 13, wherein the step of forming the infrared detection element further comprises:
providing a first semiconductor layer between the first electrode and the light-absorbing layer and providing a second semiconductor layer between the light-absorbing layer and the second electrode.

20. The method of manufacturing the array substrate according to claim 19, wherein a material of the first semiconductor layer is n-type amorphous silicon, and a material of the second semiconductor layer is p-type amorphous silicon.
